(19) United States
(12) Patent Application Publication
(10) Pub. No.: US 2026/0142654 A1
(43) Pub. Date: May 21, 2026

(54) SOLID-STATE RELAY WITH TEMPERATURE CONTROL FUNCTION AND TEMPERATURE CONTROL METHOD THEREOF

(71) Applicant: Jiangsu Gold Electric Control Technology Co., Ltd., Wuxi City (CN)

(72) Inventors: Chenzhong YIN, Wuxi City (CN); Zi YIN, Wuxi City (CN); Xingcheng ZHU, Wuxi City (CN); Yan LV, Wuxi City (CN)

(21) Appl. No.: 19/372,741

(22) Filed: Oct. 29, 2025

(30) Foreign Application Priority Data
Nov. 21, 2024 (CN) 202411671372.7

(51) Int. Cl. H03K 17/08; H05K 7/20

(52) U.S. Cl. CPC H03K 17/08; H05K 7/20136; H05K 7/20409; H03K 2017/0806

(57) ABSTRACT

A solid-state relay with a temperature control function and a temperature control method thereof are provided, relating to the technical field of relays. The solid-state relay includes a relay housing component on which four expansion control components are mounted. The four expansion control components are configured for thermal expansion. The relay housing component is internally provided with a lifting switch component. The four expansion control components are configured to control the ascending and descending of the lifting switch component. Two terminal contacts are mounted on the controlled lifting switch component.

### CROSS-REFERENCE TO RELATED APPLICATION

This patent application claims the benefit and priority of Chinese Patent Application No. 202411671372.7 filed with the China National Intellectual Property Administration on Nov. 21, 2024, the disclosure of which is incorporated by reference herein in its entirety as part of the present application.

### TECHNICAL FIELD

The present disclosure relates to the technical field of relays, and in particular to a solid-state relay with a temperature control function and a temperature control method thereof.

### BACKGROUND

A relay is an electrical control device, which causes a predetermined step change of a controlled variable in an electrical output circuit when the change of an input variable meets the specified requirements. In a solid-state relay, an optocoupler is typically used for signal control. The solid-state relay is widely used due to the advantages such as fast response, but in practical applications of the solid-state relay, the main board of the optocoupler tends to heat up during frequent switching operations, so most of the current solid-state relays are equipped with base plates that can dissipate heat. However, the current solid-state relay is inconvenient to implement temperature control by switching a main board, and issues such as damage to the optocoupler and difficulty in replacing fuses also arise. Additionally, the current solid-state relay is inconvenient to deactivate an overheated main board to allow it to cool down, conventional ventilation cooling is difficult to achieve a good heat dissipation effect on continuous use of the main board, and it is also inconvenient to control the ventilation volume automatically according to the temperature, so the heat dissipation effect is poor. The current solid-state relay is also inconvenient for explosion-proof pressure relief, and a full-sealed structure breakdown accident is likely to cause an explosion, which is inconvenient for explosion-proof alarm warning.

To this end, a solid-state relay with a temperature control function and a temperature control method thereof are proposed.

### SUMMARY

It is an object of the present disclosure to provide a solid-state relay with a temperature control function and a temperature control method thereof, in order to solve the problems raised in the above background art.

In order to achieve the object described above, the present disclosure provides the following technical solution: a solid-state relay with a temperature control function and a temperature control method thereof, including a relay housing component on which four expansion control components are mounted, where the four expansion control components are configured for thermal expansion; the relay housing component is internally provided with a lifting switch component; the four expansion control components are configured to control ascending and descending of the lifting switch component; two terminal contacts are mounted on the controlled lifting switch component, and the two terminal contacts are respectively attached to the relay housing component; two pulling auxiliary components are mounted on the lifting switch component; an enclosure connector is fixedly mounted on the relay housing component; the two pulling auxiliary components are connected to a bottom of the enclosure connector; an exhaust component is mounted on the enclosure connector; the exhaust component is configured for cooling ventilation; a switch control device is mounted on the exhaust component; the switch control device is configured to control turning on and turning off of heat dissipation and cooling; the relay housing component includes: a mounting housing and spring terminal tabs, four spring terminal tabs being fixedly mounted on an inner side of the mounting housing; where the four spring terminal tabs are grouped in pairs; the mounting housing is provided with four connection terminals; and the four spring terminal tabs are respectively connected to the connection terminals on the mounting housing.

In some embodiments, the two terminal contacts include: terminal connection boards and insulating strips, where each of two sides of each of two optocoupler main boards is electrically connected with a corresponding one of the terminal connection boards, and each of terminal connection boards is formed of two terminals; the terminal connection boards between the two optocoupler main boards are spaced apart by the insulating strips; each of the insulating strips is embedded between two adjacent ones of the terminal connection boards; four terminal connection boards are fixedly mounted on two sides of the connecting frame; and the four spring terminal tabs are elastically attached to four terminals on two of the four terminal connection boards on an upper part.

In some embodiments, the lifting switch component includes: an upper main board mounting ring, sliding limit grooves, a connecting frame, a lower main board mounting ring, optocoupler main boards, an push rod, and movable magnets, where four corners of the upper main board mounting ring are respectively slidably mounted on inner sides of the four sliding limit blocks; the upper main board mounting ring is provided with four sliding limit grooves, and the pushing limit plate is slidably mounted inside a corresponding one of the four sliding limit grooves; the connecting frame is fixedly mounted at a bottom of the upper main board mounting ring, and the lower main board mounting ring is fixedly mounted at a bottom of the connecting frame; four corners of the lower main board mounting ring are respectively slidably mounted on the inner sides of the four sliding limit blocks; the upper main board mounting ring and the lower main board mounting ring are respectively fixedly mounted with the optocoupler main boards; the push rod is fixedly mounted onto the upper main board mounting ring; two movable magnets are provided, and the two movable magnets are respectively fixedly mounted on the upper main board mounting ring and the lower main board mounting ring; one of the two movable magnets on the upper main board mounting ring is located at a top, and another one of the two movable magnets on the lower main board mounting ring is located at a bottom; the one of the two the movable magnets at the bottom magnetically connects to the lower fixed magnet; and each of the four sliding limit grooves has a thickness greater than that of the pushing limit plate.

In some embodiments, the expansion control components each include: an expansion piston cylinder, a lifting piston rod, a pushing limit plate, and mercury, where the expansion piston cylinder is fixedly mounted on the base plate; the lifting piston rod is slidably mounted inside the expansion piston cylinder; the pushing limit plate is fixedly mounted on the lifting piston rod; the expansion piston cylinder is internally provided with the mercury, and the mercury is located at a bottom of the lifting piston rod.

In some embodiments, the two pulling auxiliary components includes: lifting connecting plates and tension springs, where two lifting connecting plates are fixedly mounted on the connecting frame; the tension springs are fixedly mounted on two sides of the two lifting connecting plates; and end portions of two of the tension springs at a bottom part are fixedly mounted on a top of the base plate.

In some embodiments, the exhaust component includes: an exhaust pipe and an exhaust bellows, where the exhaust pipe is fixedly mounted on the enclosure fixed plate; the exhaust pipe is located outside the fixed closure plate; and the exhaust bellows is fixedly mounted on the exhaust pipe.

In some embodiments, the relay housing component further includes: a base plate, heat dissipation fins, a lower fixed magnet, and sliding limit blocks, where the base plate is fixedly mounted at a bottom of the mounting housing; a row of the heat dissipation fins are fixedly mounted at a bottom of the base plate; the lower fixed magnet is fixedly embedded onto the base plate; four sliding limit blocks are fixedly mounted inside the mounting housing, and the four sliding limit blocks are configured to slidably mount the lifting switch component.

In some embodiments, the enclosure connector includes: an enclosure fixed plate, an upper fixing magnet, a fixed closure plate and a warning light, where the enclosure fixed plate is fixedly mounted on the mounting housing; the upper fixing magnet is fixedly mounted at a bottom of the enclosure fixed plate; the upper fixing magnet corresponds to one of the two movable magnets; the enclosure fixed plate is connected to two of the tension springs at a top part; the fixed closure plate is fixedly mounted in a middle of the enclosure fixed plate; the fixed closure plate is provided with a circle of through slots; the warning light is fixedly mounted on the enclosure fixed plate; and the fixed closure plate is configured for exhaust ventilation.

In some embodiments, the switch control device includes: a cooling control sliding column, a closing plate, a microswitch and a connecting tension spring, where the cooling control sliding column is slidably mounted to the fixed closure plate; the closing plate is fixedly mounted at a top of the cooling control sliding column; the closing plate is provided with a circle of through slots; the cooling control sliding column is of a hexagonal column structure; the circle of through slots formed in the closing plate are misaligned with the circle of through slots formed in the fixed closure plate; the microswitch is fixedly mounted at a bottom of the cooling control sliding column; the microswitch is located above the push rod; the connecting tension spring is sleeved on the cooling control sliding column; and the connecting tension spring is connected between the closing plate and the fixed closure plate; the microswitch is electrically connected to the warning light.

The temperature control method of the solid-state relay with a temperature control function includes:
1), when excessive heating of one of optocoupler main boards causes mercury to expand, driving a lifting piston rod to rise, pushing an upper main board mounting ring up by pushing a limit plate inside a corresponding one of sliding limit grooves, driving a lower one of the optocoupler main boards to move upward, and driving ones of terminal connection boards at a lower part to move upward to engage with the spring terminal tabs, enabling an electrical connection, switching to using the lower one of the optocoupler main boards for a coupling control operation, and enabling an upper one of the optocoupler main boards to cool down;
2), driving the lifting switch component to move upward by thermal expansion of the mercury, driving a cooling control sliding column to separate a closing plate from a fixed closure plate, where at this time the closing plate is no longer attached to the fixed closure plate, and ventilation and cooling are achieved through through slots in the closing plate and in the fixed closure plate.

Compared with the conventional technology, the present disclosure achieves the following beneficial effects.

The lifting switch component is used in the present disclosure, so that a liftable structure of the lifting switch component is utilized, it is possible to replace two optocoupler main boards, and when an optocoupler main board experiences a short circuit or overheating damage, it is swapped out, thereby extending the service life, especially for applications requiring real-time electrical control, where replacement can be performed; additionally, in the event of overheating, the optocoupler main boards may be alternated to reduce temperature more directly, which solves the problem of slow heat dissipation when the optocoupler main board is under load; and the alternating use of the two optocoupler main boards also enhances durability.

The pulling auxiliary components are used in cooperation with the movable magnet, the lower fixed magnet and the upper fixed magnet, so that the lifting switching speed and stability of the lifting switch component can be improved, and a magnetic attraction positioning structure is utilized to ensure a stable electrical connection, while the tension springs are used to provide a buffering effect.

The exhaust component can be used to facilitate an exhaust cooling operation, and the exhaust bellows can pass directly through an electrical cabinet, which can assist in the role of explosion-proof extraction, thereby solving the problem of an excessive pressure inside the electrical cabinet in the occurrence of deflagration or other special accidents in this structure; and the warning light enables this structure to provide an explosion-proof warning, so that a warning is issued when the optocoupler main board is replaced.

By using the switch control device and utilizing the cooling control sliding column, it is possible to realize an explosion-proof operation through compression-driven sliding, and prevent an excessive internal pressure and potential explosion in a fully sealed relay during overheating. By utilizing the elastic connection of the connecting tension spring, in the presence of air pressure inside the present structure, the closing plate may be separated from the fixed closure plate to allow discharge; and as the mercury is thermally expanded to move the lifting switch component upward, the closing plate is automatically separated from the fixed closure plate, initiating active heat dissipation, which enables more efficient heat dissipation.

### BRIEF DESCRIPTION OF THE DRAWINGS

FIG. 1 shows a schematic diagram of an entire structure of the present disclosure.

FIG. 2 shows a schematic diagram of an internal structure of the present disclosure.

FIG. 3 shows a schematic diagram of positions of terminal connection boards of the present disclosure.

FIG. 4 shows a structural sectional view of an exhaust component of the present disclosure.

FIG. 5 shows a schematic structural diagram of a relay housing component of the present disclosure.

FIG. 6 shows a structural enlarged view of part B in FIG. 4 of the present disclosure.

FIG. 7 shows a schematic structural diagram of an expansion control component of the present disclosure.

FIG. 8 shows a schematic structural diagram of a lifting switch component component of the present disclosure.

FIG. 9 shows a structural enlarged view of part C in FIG. 7 of the present disclosure.

FIG. 10 shows a schematic structural diagram of an enclosure connector of the present disclosure.

FIG. 11 shows a schematic structural diagram of a switch control device of the present disclosure.

In the figures: 1 relay housing component; 101 mounting housing; 1011 spring terminal tab; 102 base plate; 1021 heat dissipation fin; 103 lower fixed magnet; 104 sliding limit block; 105 connection terminal; 2 expansion control component; 201 expansion piston cylinder; 202 lifting piston rod; 203 pushing limit plate; 204 mercury; 3 lifting switch component; 301 upper main board mounting ring; 3011 sliding limit groove; 302 connecting frame; 303 lower main board mounting ring; 304 optocoupler main board; 305 push rod; 306 movable magnet; 4 terminal contact; 401 terminal connection board; 4011 terminal; 402 insulating strip; 5 pulling auxiliary component; 501 lifting connecting plate; 502 tension spring; 6 enclosure connector; 601 enclosure fixed plate; 602 upper fixed magnet; 603 fixed closure plate; 604 warning light; 7 exhaust component; 701 exhaust pipe; 702 exhaust bellows; 8 switch control device; 801 cooling control sliding column; 802 closing plate; 803 microswitch; 804 connecting tension spring.

### DETAILED DESCRIPTION OF THE EMBODIMENTS

The technical solutions in the embodiments of the present disclosure will be clearly and completely described below in conjunction with the accompanying drawings in the embodiments of the present disclosure. Apparently, the embodiments described are merely some rather than all of the embodiments of the present disclosure. Based on the embodiments in the present disclosure, all other embodiments obtained by those of ordinary skill in the art without creative effort belong to the scope of protection of the present disclosure.

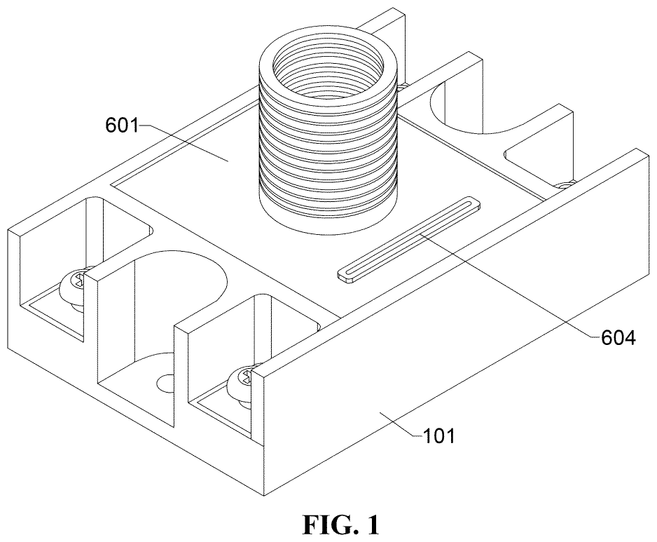

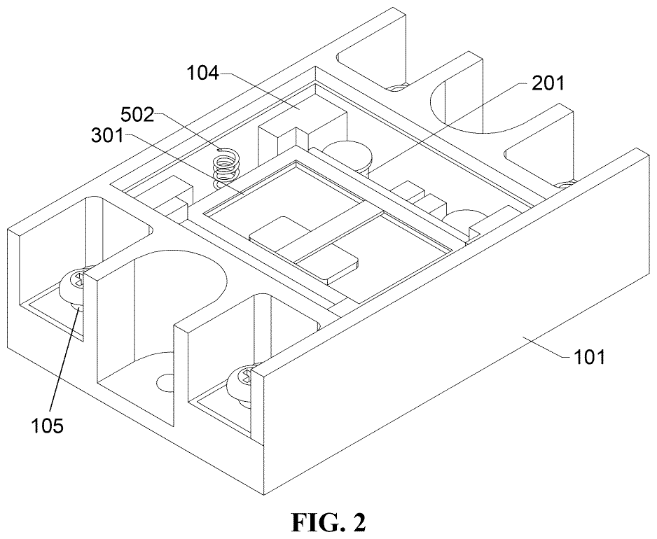

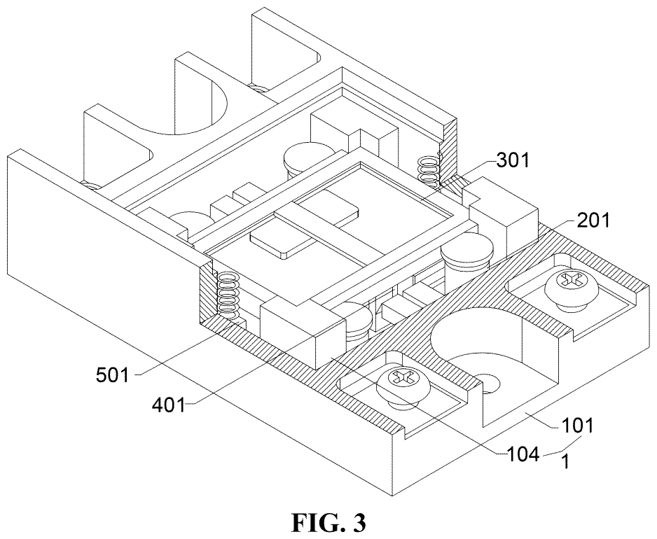

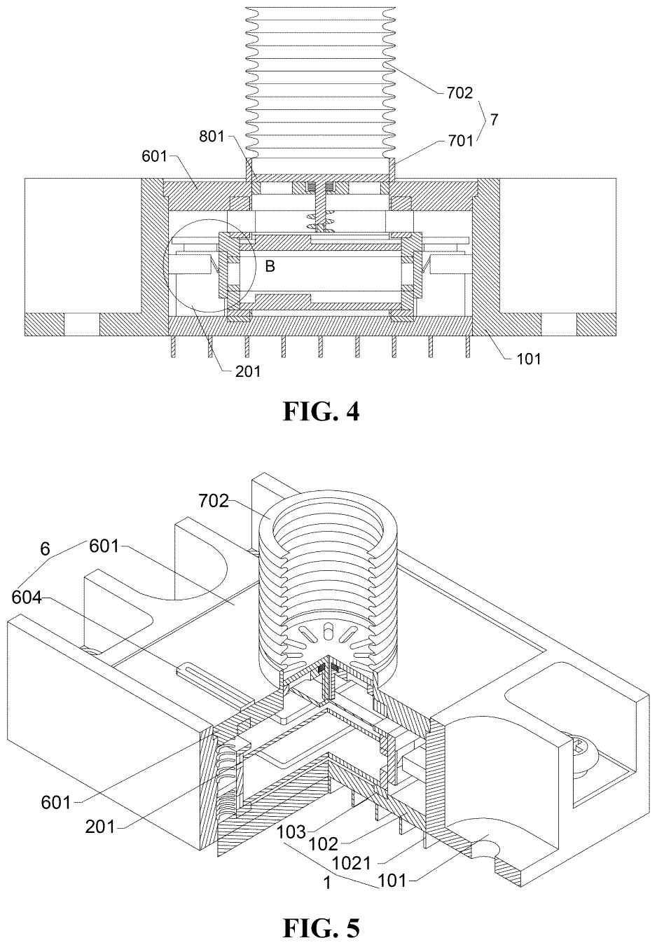

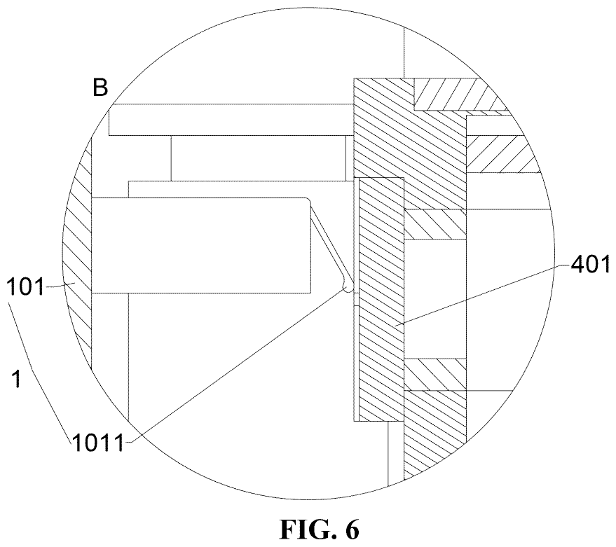

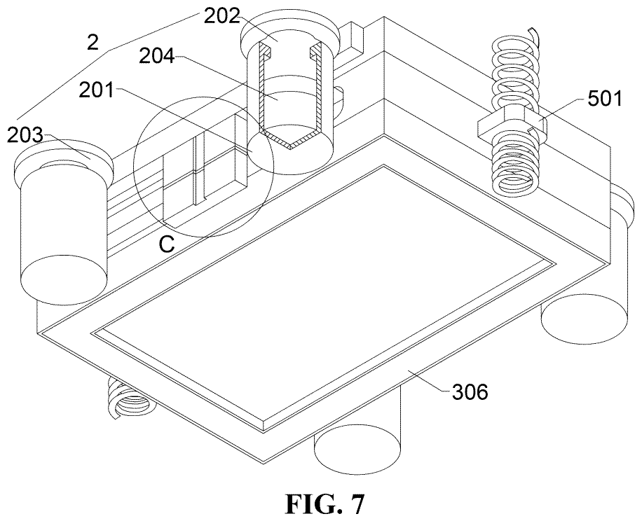

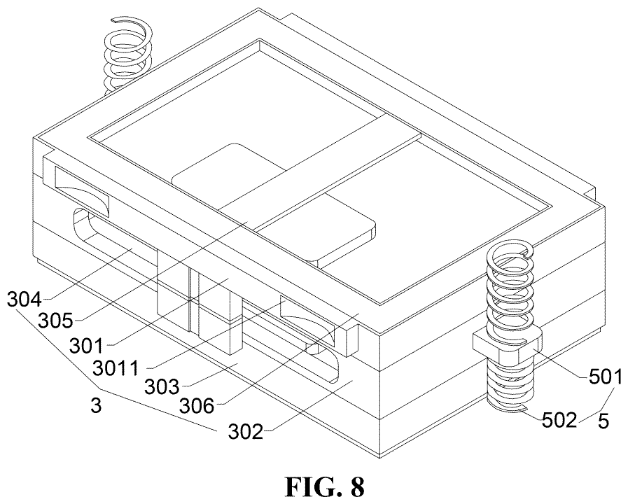

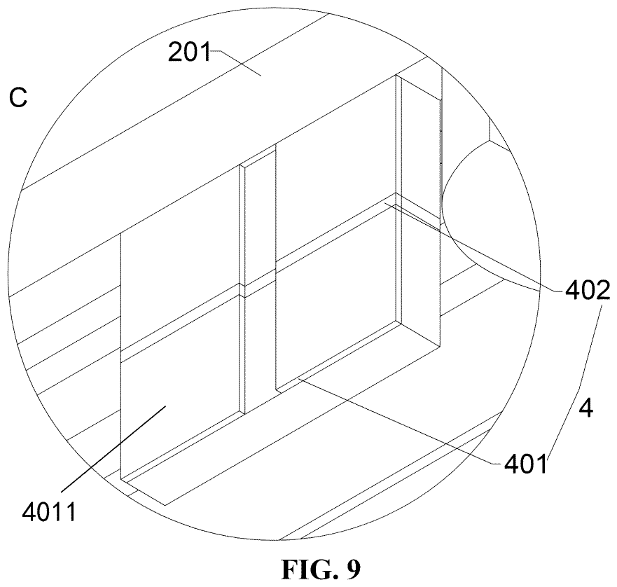

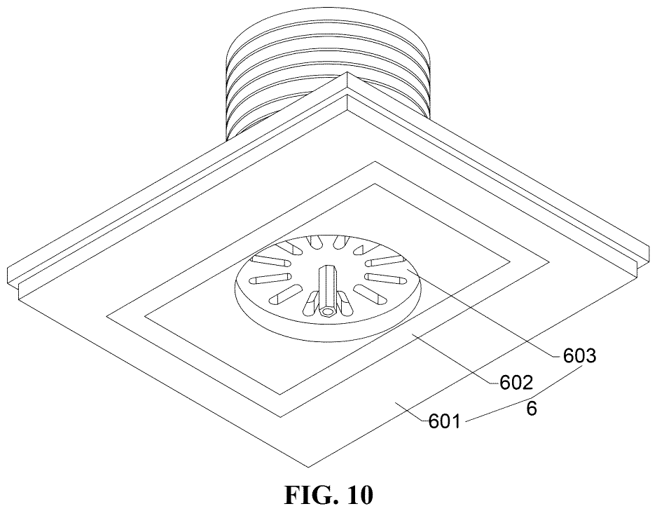

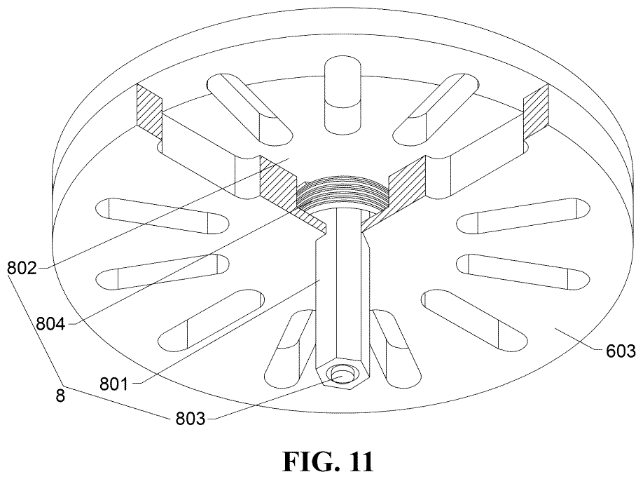

Embodiment 1: referring to FIGS. 1-11, a technical solution of the present disclosure is provided. A solid-state relay with a temperature control function and a temperature control method thereof are proposed, the solid-state relay with a temperature control function includes a relay housing component 1 on which four expansion control components 2 are mounted. The four expansion control components 2 are configured for thermal expansion. The relay housing component 1 is internally provided with a lifting switch component 3. The four expansion control components 2 are configured to control the ascending and descending of the lifting switch component 3. Two terminal contacts 4 are mounted on the controlled lifting switch component 3, and the two terminal contacts 4 are respectively attached to the relay housing component 1. Two pulling auxiliary components 5 are mounted on the lifting switch component 3. An enclosure connector 6 is fixedly mounted on the relay housing component 1. The two pulling auxiliary components 5 are connected to the bottom of the enclosure connector 6. An exhaust component 7 is mounted on the enclosure connector 6. The exhaust component 7 is configured for cooling ventilation. A switch control device 8 is mounted on the exhaust component 7. The switch control device 8 is configured to control turning on and turning off of heat dissipation and cooling. The relay housing component 1 includes a mounting housing 101 and spring terminal tabs 1011. Four spring terminal tabs 1011 are fixedly mounted on an inner side of the mounting housing 101. The four spring terminal tabs 1011 are grouped in pairs. The mounting housing 101 is provided with four connection terminals. The four spring terminal tabs 1011 are respectively connected to the connection terminals on the mounting housing 101.

The relay housing component 1 further includes a base plate 102, heat dissipation fins 1021, a lower fixed magnet 103, and sliding limit blocks 104. The base plate 102 is fixedly mounted at the bottom of the mounting housing 101. A row of the heat dissipation fins 1021 are fixedly mounted at the bottom of the base plate 102. The lower fixed magnet 103 is fixedly embedded onto the base plate 102. Four sliding limit blocks 104 are fixedly mounted inside the mounting housing 101, and the four sliding limit blocks 104 are configured to slidably mount the lifting switch component 3. Each of the expansion control component 2 includes an expansion piston cylinder 201, a lifting piston rod 202, a pushing limit plate 203, and mercury 204. The expansion piston cylinders 201 are fixedly mounted on the base plate 102. The lifting piston rods 202 are slidably mounted inside the expansion piston cylinders 201. The pushing limit plate 203 are fixedly mounted on the lifting piston rods 202. The expansion piston cylinders 201 are internally provided with the mercury 204, and the mercury 204 is located at the bottoms of the lifting piston rods 202. The lifting switch component 3 includes an upper main board mounting ring 301, sliding limit grooves 3011, a connecting frame 302, a lower main board mounting ring 303, optocoupler main boards 304, an push rod 305, and movable magnets 306. The sliding limit groove 3011 has a thickness larger than that of the pushing limit plate 203. Four corners of the upper main board mounting ring 301 are respectively slidably mounted on inner sides of the four sliding limit blocks 104. The upper main board mounting ring 301 is provided with four sliding limit grooves 3011, and the pushing limit plates 203 are respectively slidably mounted inside the four sliding limit grooves 3011. The connecting frame 302 is fixedly mounted at the bottom of the upper main board mounting ring 301, and the lower main board mounting ring 303 is fixedly mounted at the bottom of the connecting frame 302. Four corners of the lower main board mounting ring 303 are respectively slidably mounted on the inner sides of the four sliding limit blocks 104. The upper main board mounting ring 301 and the lower main board mounting ring 303 are respectively fixedly mounted with the optocoupler main boards 304. The push rod 305 is fixedly mounted onto the upper main board mounting ring 301. Two movable magnets 306 are provided, and the two movable magnets 306 are respectively fixedly mounted on the upper main board mounting ring 301 and the lower main board mounting ring 303. The movable magnet 306 on the upper main board mounting ring 301 is located at the top, and the movable magnet 306 on the lower main board mounting ring 303 is located at the bottom. The movable magnet 306 at the bottom magnetically connects to the lower fixed magnet 103. The lifting switch component 3 is used so that a liftable structure of the lifting switch component 3 may be utilized, it is possible to replace two optocoupler main boards 304, and when an optocoupler main board 304 experiences a short circuit or overheating damage, it can be swapped out, thereby extending the service life, especially for applications requiring real-time electrical control, where replacement can be performed; additionally, in the event of overheating, the optocoupler main boards 304 may be alternated to reduce temperature more directly, which solves the problem of slow heat dissipation when the optocoupler main board 304 is under load; the alternating use of the two optocoupler main boards 304 also enhances durability. An expansion control operation can be performed by the expansion control components 2, thereby ensuring reasonable telescopic control without the need for electrical power, and providing a more direct control effect. When excessive heating of the optocoupler main board 304 causes the mercury 204 to expand, the lifting piston rods 202 are driven upward, the pushing limit plates 203 inside the sliding limit grooves 3011 push the upper main board mounting ring 301 upward. At this point, the lower terminal connection board 401 moves upward to make contact with the spring terminal tabs 1011, thereby completing an electrical connection. Then the structure can use the lower optocoupler main board 304 for coupling control, while the upper optocoupler main board 304 is disconnected to allow for cooling.

The terminal contact 4 includes: terminal connection boards 401 and insulating strips 402. Each of two sides of each of two optocoupler main boards (304) is electrically connected with a corresponding one of the terminal connection boards 401, and each of the terminal connection boards 401 is formed of two terminals. The terminal connection boards 401 between the two optocoupler main boards 304 are spaced apart by the insulating strips 402. The insulating strip 402 is embedded between two adjacent terminal connection boards 401. Four terminal connection boards 401 are fixedly mounted on two sides of the connecting frame 302. The four spring terminal tabs 1011 are elastically attached to four terminals on two terminal connection boards 401 on an upper part. Each pulling auxiliary component 5 includes a lifting connecting plate 501 and tension springs 502. Two lifting connecting plates 501 are fixedly mounted on the connecting frame 302. The tension springs 502 are fixedly mounted on two sides of the two lifting connecting plates 501. End portions of two tension springs 502 at the bottom are fixedly mounted on the top of the base plate 102. The pulling auxiliary components 5 are used in cooperation with the movable magnet 306, the lower fixed magnet 103 and the upper fixed magnet 602, so that the lifting switching speed and stability of the lifting switch component 3 can be improved, and a magnetic attraction positioning structure is utilized to ensure a stable electrical connection, while the tension springs 502 are used to provide a buffering and pulling effect during the movement of the connecting frame 302, featuring a simple and practical structure. The terminal contact 4 allows the use of a separate terminal connection board 401, and in cooperation with the spring terminal tab 1011, the electrical connection is direct and efficient, which can be automatically regulated as the temperature rises and decreases. Under the attraction of the upper fixed magnet 602 and the lower fixed magnet 103, the closer movable magnet 306 can be magnetically attracted to speed up the switching operation, which is more practical. With the fact that the thickness of the sliding limit groove 3011 is larger than that of the pushing limit plate 203, the upward or downward movement of the pushing limit plate 203 to push the sliding limit groove 3011 does not affect the magnetic positioning of the main board mounting ring 301 which is achieved through the movable magnet 306.

The enclosure connector 6 includes an enclosure fixed plate 601, an upper fixing magnet 602, a fixed closure plate 603 and a warning light 604. The enclosure fixed plate 601 is fixedly mounted on the mounting housing 101. The upper fixing magnet 602 is fixedly mounted at the bottom of the enclosure fixed plate 601. The upper fixing magnet 602 corresponds to the movable magnet 306. The enclosure fixed plate 601 is connected to the two tension springs 502 at the top. The fixed closure plate 603 is fixedly mounted in the middle of the enclosure fixed plate 601. The fixed closure plate 603 is provided with a circle of through slots. The warning light 604 is fixedly mounted on the enclosure fixed plate 601. The fixed closure plate 603 is configured for exhaust ventilation. The exhaust component 7 includes an exhaust pipe 701 and an exhaust bellows 702. The exhaust pipe 701 is fixedly mounted on the enclosure fixed plate 601. The exhaust pipe 701 is located outside the fixed closure plate 603. The exhaust bellows 702 is fixedly mounted on the exhaust pipe 701. The exhaust component 7 can be used to facilitate an exhaust cooling operation, and the exhaust bellows 702 can pass directly through an electrical cabinet, which can assist in the role of explosion-proof extraction, thereby solving the problem of an excessive pressure inside the electrical cabinet in the occurrence of deflagration or other special accidents. The cooperation of the exhaust pipe 701 with the heat dissipation fins 1021 can achieve accelerated heat dissipation when overheating. The warning light 604 enables this structure to provide an explosion-proof warning, so that a warning is issued when the optocoupler main board 304 is replaced.

With regard to embodiment 2, on the basis of embodiment 1, the switch control device 8 includes a cooling control sliding column 801, a closing plate 802, a microswitch 803 and a connecting tension spring 804. The cooling control sliding column 801 is slidably mounted to the fixed closure plate 603. The closing plate 802 is fixedly mounted at the top of the cooling control sliding column 801. The closing plate 802 is provided with a circle of through slots. The cooling control sliding column 801 is of a hexagonal column structure. The circle of through slots formed in the closing plate 802 are misaligned with the circle of through slots formed in the fixed closure plate 603. The microswitch 803 is fixedly mounted at the bottom of the cooling control sliding column 801. The microswitch 803 is located above the push rod 305. The connecting tension spring 804 is sleeved on the cooling control sliding column 801. The connecting tension spring 804 is connected between the closing plate 802 and the fixed closure plate 603. By using the switch control device 8 and utilizing the cooling control sliding column 801, it is possible to realize an explosion-proof operation through compression-driven sliding, and prevent an excessive internal pressure and potential explosion in a fully sealed relay during overheating. By utilizing the elastic connection of the connecting tension spring 804 and the electrical connection between the microswitch 803 and the warning light 604, the structure allows timely release of an internal air pressure, and as the mercury 204 is thermally expanded to move the lifting switch component 3 upward, the closing plate 802 is automatically separated from the fixed closure plate 603, initiating active heat dissipation, which is more rational and enables more efficient heat dissipation; the length of the exhaust bellows 702 can be adjusted according to requirements, and as the mercury 204 is thermally expanded to move the lifting switch component 3 upward, the push rod 305 can be moved to press the microswitch 803, at this time the microswitch 803 can control the illumination of the warning light 604 to issue a warning. The lifting switch component 3 can drive the closing plate 802 to separate from the fixed closure plate 603, at this time the closing plate 802 is no longer attached to the fixed closure plate 603, allowing the through slots to be opened, which enables air circulation and accelerates cooling.

The temperature control method of the solid-state relay with a temperature control function includes:
1), when excessive heating of the optocoupler main board 304 causes the mercury 204 to expand, the lifting piston rod 202 is driven to rise, the pushing limit plates 203 inside the sliding limit grooves 3011 push the upper main board mounting ring 301 up, the lower optocoupler main board 304 is is driven to move upward, and at this time the lower terminal connection boards 401 moves upward to engage with the spring terminal tabs 1011, enabling an electrical connection, then it is switched to using the lower optocoupler main board 304 for a coupling control operation, and the upper optocoupler main board 304 cools down; and
2), the mercury 204 is thermally expanded to move the lifting switch component 3 upward, which drives the cooling control sliding column 801 to separate the closing plate 802 from the fixed closure plate 603, and at this time the closing plate 802 is no longer attached to the fixed closure plate 603, and ventilation and cooling are achieved through the through slots in the closing plate 802 and in the fixed closure plate 603.

The working principle of this embodiment is as follows. First, the mounting housing 101 is mounted in the electrical cabinet or the like, an electrical connection is established by wiring the four connection terminals on the mounting housing 101. When excessive heating of the optocoupler main board 304 causes the mercury 204 to expand, the lifting piston rods 202 may be driven to rise, the pushing limit plates 203 inside the sliding limit grooves 3011 push the upper main board mounting ring 301 up, then the lower optocoupler main board 304 is moved upward. And at this time the lower terminal connection boards 401 move upward to engage with the spring terminal tabs 1011, enabling an electrical connection, then this structure may use the lower optocoupler main board 304 for a coupling control operation, and the upper optocoupler main board 304 may be disconnected to achieve the purpose of cooling down. When the mercury 204 expands under heating or contracts under cooling, the pushing limit plates 203 may be driven to move up or down for adjustment, which in turn drives the upward or downward movement of the upper main board mounting ring 301 and the lower main board mounting ring 303, and as the two movable magnets 306 move simultaneously, under the attraction of the upper fixed magnet 602 and the lower fixed magnet 103, it is possible to magnetically attract a closer movable magnet 306 when the movable magnet 306 approaches, thereby accelerating the switching operation. In the presence of an internal pressure in the present structure, the elastic connection of the connecting tension spring 804 and the air pressure may separate the closing plate 802 from the fixed closure plate 603, at this time the closing plate 802 is no longer attached to the fixed closure plate 603, the through slots thereof are also opened, and the air pressure may be discharged in time. The length of the exhaust bellows 702 can be adjusted according to requirements, and as the mercury 204 is thermally expanded to move the lifting switch component 3 upward, the push rod 305 can be moved to press the microswitch 803, at this time the microswitch 803 can control the illumination of the warning light 604 to issue a warning. As the lifting switch component 3 continuously moves up, the cooling control sliding column 801 may be driven to separate the closing plate 802 from the fixed closure plate 603, and at this time the closing plate 802 is no longer attached to the fixed closure plate 603, and ventilation and cooling are achieved through the through slots in the closing plate 802 and in the fixed closure plate 603.

It should be noted that in this specification, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, so that a process, a method, an article, or a device that includes a list of elements not only includes those elements but also includes other elements that are not listed, or further includes elements inherent to such a process, method, article, or device.

Although embodiments of the present disclosure have been shown and described, it will be appreciated by those of ordinary skill in the art that various changes, modifications, substitutions, and variations may be made to the embodiments without departing from the principle and spirit of the present disclosure, and the scope of the present disclosure is defined by the appended claims and their equivalents.

What is claimed is:

1. A solid-state relay with a temperature control function, comprising a relay housing component (1) on which four expansion control components (2) are mounted, wherein the relay housing component (1) is internally provided with a lifting switch component (3); the four expansion control components (2) are configured to control ascending and descending of the lifting switch component (3);
the expansion control components (2) each comprise: an expansion piston cylinder (201), a lifting piston rod (202), a pushing limit plate (203), and mercury (204); the lifting piston rod (202) is slidably mounted inside the expansion piston cylinder (201); the pushing limit plate (203) is fixedly mounted on the lifting piston rod (202); the expansion piston cylinder (201) is internally provided with the mercury (204), and the mercury (204) is located at a bottom of the lifting piston rod (202);
the lifting switch component (3) comprises: an upper main board mounting ring (301), sliding limit grooves (3011), a connecting frame (302), a lower main board mounting ring (303), optocoupler main boards (304), an push rod (305), and movable magnets (306);
when excessive heating of one of the optocoupler main boards (304) causes the mercury (204) to expand, the lifting piston rod (202) is driven to rise, the pushing limit plate (203) inside a corresponding one of the sliding limit grooves (3011) pushes the upper main board mounting ring (301) up, a lower one of the optocoupler main boards (304) is driven to move upward, at this time it is switched to using the lower one of the optocoupler main boards (304) for a coupling control operation, and an upper one of the optocoupler main boards (304) cools down.

2. The solid-state relay with a temperature control function according to claim 1, wherein two terminal contacts (4) are mounted on the lifting switch component (3), and the two terminal contacts (4) are respectively attached to the relay housing component (1);
two pulling auxiliary components (5) are mounted on the lifting switch component (3);
an enclosure connector (6) is fixedly mounted on the relay housing component (1); the two pulling auxiliary components (5) are connected to a bottom of the enclosure connector (6);
an exhaust component (7) is mounted on the enclosure connector (6); the exhaust component (7) is configured for cooling ventilation;
a switch control device (8) is mounted on the exhaust component (7); the switch control device (8) is configured to control turning on and turning off of heat dissipation and cooling;
the relay housing component (1) comprises: a mounting housing (101) and spring terminal tabs (1011), four spring terminal tabs (1011) being fixedly mounted on an inner side of the mounting housing (101); wherein the four spring terminal tabs (1011) are grouped in pairs; the mounting housing (101) is provided with four connection terminals; and the four spring terminal tabs (1011) are respectively connected to the connection terminals on the mounting housing (101).

3. The solid-state relay with a temperature control function according to claim 2, wherein the relay housing component (1) further comprises: a base plate (102), heat dissipation fins (1021), a lower fixed magnet (103), and sliding limit blocks (104), wherein the base plate (102) is fixedly mounted at a bottom of the mounting housing (101); a row of the heat dissipation fins (1021) are fixedly mounted at a bottom of the base plate (102); the lower fixed magnet (103) is fixedly embedded onto the base plate (102); four sliding limit blocks (104) are fixedly mounted inside the mounting housing (101), and the four sliding limit blocks (104) are configured to slidably mount the lifting switch component (3); the expansion piston cylinder (201) is fixedly mounted on the base plate (102).

4. The solid-state relay with a temperature control function according to claim 3, wherein four corners of the upper main board mounting ring (301) are respectively slidably mounted on inner sides of the four sliding limit blocks (104); the upper main board mounting ring (301) is provided with four sliding limit grooves (3011), and the pushing limit plate (203) is slidably mounted inside a corresponding one of the four sliding limit grooves (3011); the connecting frame (302) is fixedly mounted at a bottom of the upper main board mounting ring (301), and the lower main board mounting ring (303) is fixedly mounted at a bottom of the connecting frame (302); four corners of the lower main board mounting ring (303) are respectively slidably mounted on the inner sides of the four sliding limit blocks (104); the upper main board mounting ring (301) and the lower main board mounting ring (303) are respectively fixedly mounted with the optocoupler main boards (304); the push rod (305) is fixedly mounted onto the upper main board mounting ring (301); two movable magnets (306) are provided, and the two movable magnets (306) are respectively fixedly mounted on the upper main board mounting ring (301) and the lower main board mounting ring (303); one of the two movable magnets (306) on the upper main board mounting ring (301) is located at a top, and another one of the two movable magnets (306) on the lower main board mounting ring (303) is located at a bottom; the one of the two the movable magnets (306) at the bottom magnetically connects to the lower fixed magnet (103); and each of the four sliding limit grooves (3011) has a thickness greater than that of the pushing limit plate (203).

5. The solid-state relay with a temperature control function according to claim 4, wherein the two terminal contacts (4) comprise: terminal connection boards (401) and insulating strips (402), wherein each of two sides of each of two optocoupler main boards (304) is electrically connected with a corresponding one of the terminal connection boards (401), and each of terminal connection boards (401) is formed of two terminals; the terminal connection boards (401) between the two optocoupler main boards (304) are spaced apart by the insulating strips (402); each of the insulating strips (402) is embedded between two adjacent ones of the terminal connection boards (401); four terminal connection boards (401) are fixedly mounted on two sides of the connecting frame (302); and the four spring terminal tabs (1011) are elastically attached to four terminals on two of the four terminal connection boards (401) on an upper part.

6. The solid-state relay with a temperature control function according to claim 5, wherein the two pulling auxiliary components (5) comprises: lifting connecting plates (501) and tension springs (502), wherein two lifting connecting plates (501) are fixedly mounted on the connecting frame (302); the tension springs (502) are fixedly mounted on two sides of the two lifting connecting plates (501); and end portions of two of the tension springs (502) at a bottom part are fixedly mounted on a top of the base plate (102).

7. The solid-state relay with a temperature control function according to claim 6, wherein the enclosure connector (6) comprises: an enclosure fixed plate (601), an upper fixing magnet (602), a fixed closure plate (603) and a warning light (604), wherein the enclosure fixed plate (601) is fixedly mounted on the mounting housing (101); the upper fixing magnet (602) is fixedly mounted at a bottom of the enclosure fixed plate (601); the upper fixing magnet (602) corresponds to one of the two movable magnets (306); the enclosure fixed plate (601) is connected to two of the tension springs (502) at a top part; the fixed closure plate (603) is fixedly mounted in a middle of the enclosure fixed plate (601); the fixed closure plate (603) is provided with a circle of through slots; the warning light (604) is fixedly mounted on the enclosure fixed plate (601); and the fixed closure plate (603) is configured for exhaust ventilation.

8. The solid-state relay with a temperature control function according to claim 7, wherein the exhaust component (7) comprises: an exhaust pipe (701) and an exhaust bellows (702), wherein the exhaust pipe (701) is fixedly mounted on the enclosure fixed plate (601); the exhaust pipe (701) is located outside the fixed closure plate (603); and the exhaust bellows (702) is fixedly mounted on the exhaust pipe (701).

9. The solid-state relay with a temperature control function according to claim 8, wherein the switch control device (8) comprises: a cooling control sliding column (801), a closing plate (802), a microswitch (803) and a connecting tension spring (804), wherein the cooling control sliding column (801) is slidably mounted to the fixed closure plate (603); the closing plate (802) is fixedly mounted at a top of the cooling control sliding column (801); the closing plate (802) is provided with a circle of through slots; the cooling control sliding column (801) is of a hexagonal column structure; the circle of through slots formed in the closing plate (802) are misaligned with the circle of through slots formed in the fixed closure plate (603); the microswitch (803) is fixedly mounted at a bottom of the cooling control sliding column (801); the microswitch (803) is located above the push rod (305); the microswitch (803) is electrically connected to the warning light (604); the connecting tension spring (804) is sleeved on the cooling control sliding column (801); and the connecting tension spring (804) is connected between the closing plate (802) and the fixed closure plate (603).

10. A temperature control method of a solid-state relay with a temperature control function, applied to the solid-state relay with a temperature control function as claimed in claim 9, steps of the method comprising:
1), when the excessive heating of the one of the optocoupler main boards (304) causes the mercury (204) to expand, driving the lifting piston rod (202) to rise, pushing the upper main board mounting ring (301) up by pushing the limit plate (203) inside a corresponding one of the sliding limit grooves (3011), driving the lower one of the optocoupler main boards (304) to move upward, and driving ones of the terminal connection boards (401) at a lower part to move upward to engage with the spring terminal tabs (1011), enabling an electrical connection, switching to using the lower one of the optocoupler main boards (304) for the coupling control operation, and enabling the upper one of the optocoupler main boards (304) to cool down;
2), driving the lifting switch component (3) to move upward by thermal expansion of the mercury (204), driving the cooling control sliding column (801) to separate the closing plate (802) from the fixed closure plate (603), wherein at this time the closing plate (802) is no longer attached to the fixed closure plate (603), and ventilation and cooling are achieved through the through slots in the closing plate (802) and in the fixed closure plate (603).
